(19) United States
(12) Patent Application Publication
(10) Pub. No.: US 2010/0101848 A1
(43) Pub. Date: Apr. 29, 2010

(54) SUBSTRATE UNIT, INFORMATION PROCESSOR AND METHOD OF MANUFACTURING SUBSTRATE UNIT

(75) Inventors: Yoshinobu Maeno, Kawasaki (JP); Keiichi Yamamoto, Kawasaki (JP); Masakazu Takesue, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/499,327

(22) Filed: Jul. 8, 2009

(30) Foreign Application Priority Data
Oct. 24, 2008 (JP) 2008-274017

(51) Int. Cl. H05K 1/18; H05K 3/30

(52) U.S. Cl. 174/260; 29/832

(57) ABSTRACT

A substrate unit includes an electronic component having a plurality of electrodes arranged in a given shape, a circuit substrate having a first face where the electronic component is mounted and the electrodes are jointed and a second face underside of the first face, and a resin-coated portion formed on the second face according to a projected area of the second face to which the given shape is projected.

### CROSS-REFERENCE TO RELATED APPLICATION

This application is based upon and claims the benefit of priority of the prior Japanese Patent Application No. 2008-274017, filed on Oct. 24, 2008, the entire contents of which are incorporated herein by reference.

### FIELD

A certain aspect of embodiments relates to a substrate unit, an information processor and a method of manufacturing a substrate unit.

### BACKGROUND

There is a case where Ball Grid Array (BGA) is used as a portion for mounting an electronic component such as a semiconductor device on a print substrate. A solder-jointing portion of the electronic component is subjected to a stress when a substrate, on which the electronic component is mounted with the BGA, is subjected to an external force. This may result in breaking of the solder-jointing portion or pad peeling.

There is a case where an underfill is coated in order to restrain the breaking of the solder-jointing portion or the pad peeling. In the underfill coating, a resin is provided between the electronic component and the print substrate.

There is known a structure in which a substrate on which an underfill is coated is processed in order to secure structural reliability after mounting of electronic components. For example, Japanese Patent Application Publication No. 11-265967 discloses a LSI (Large Scale Integration)-mounted substrate having a back face on which a stiffener having the same external shape as the LSI and a given thickness is fixed with an adhesive agent having the same effect as the underfill member.

However, the underfill has the following disadvantage. It is difficult to exchange the electronic component mounted on the substrate after coating of the underfill. An electrical test of the electronic component is carried out at a factory. The electrical test must be carried out before coating of the underfill in view of the difficulty of exchanging of parts. If the underfill is coated on a specific substrate and the substrate does not pass the electrical test, the substrate must be scrapped.

The structure, in which the stiffener is adhered to the back face of the mounting substrate, needs a process of cutting out a stiffener having a desired shape from a material and a process of adhering the stiffener to the back face of the substrate at the time of manufacturing, in addition to the process of coating the underfill. Therefore, the structure takes extra processes.

### SUMMARY

According to an aspect of the present invention, there is provided a substrate unit including an electronic component having a plurality of electrodes arranged in a given shape, a circuit substrate having a first face where the electronic component is mounted and the electrodes are jointed and a second face underside of the first face, and a resin-coated portion formed on the second face according to a projected area of the second face to which the given shape is projected.

According to another aspect of the present invention, there is provided an information processor including a substrate unit, and a chassis on which the substrate unit is mounted, wherein the substrate unit includes an electronic component having a plurality of electrodes arranged in a given shape, a circuit substrate having a first face where the electronic component is mounted and the electrodes are jointed and a second face underside of the first face, and a resin-coated portion formed on the second face according to a projected area of the second face to which the given shape is projected.

According to another aspect of the present invention, there is provided a method of manufacturing a substrate unit including jointing a plurality of electrodes of an electronic component on a first face of a circuit substrate in a given shape with a solder or a conductive adhesive agent, coating hardening resin on the second face underside of the first face according to the arrangement of the electrodes, and hardening the hardening resin and forming a resin-coated portion.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A illustrates a front view of a substrate unit in accordance with a first embodiment;

FIG. 1B illustrates a circuit substrate viewed from a second face of the substrate unit;

FIG. 2 illustrates an arrangement of electrodes of a semiconductor device;

FIG. 3A through FIG. 3D illustrate a manufacturing method of a substrate unit;

FIG. 4A through FIG. 4D illustrate a stress of a substrate unit;

FIG. 5 illustrates a reverse bend test;

FIG. 6 illustrates a distortion test;

FIG. 7 illustrates a distortion test result;

FIG. 8A (1) through FIG. 8A (3) illustrate a part of a manufacturing method of a substrate unit in accordance with a second embodiment;

FIG. 8B illustrates a cross sectional view taken along a line A-A of FIG. 8A (3);

FIG. 9A illustrates a front view of a substrate unit in accordance with a third embodiment;

FIG. 9B illustrates a circuit substrate viewed from a second face of the substrate unit;

FIG. 9C illustrates a cross sectional view taken along a line B-B of FIG. 9B;

FIG. 10A illustrates a front view of a substrate unit in accordance with a fourth embodiment;

FIG. 10B illustrates a circuit substrate viewed from a second face of the substrate unit;

FIG. 11A illustrates a front view of a substrate unit in accordance with another embodiment;

FIG. 11B illustrates a circuit substrate viewed from a second face of the substrate unit;

FIG. 12A illustrates a front view of a substrate unit in accordance with another embodiment;

FIG. 12B illustrates a circuit substrate viewed from a second face of the substrate unit;

FIG. 13A illustrates a front view of a substrate unit in accordance with another embodiment;

FIG. 13B illustrates a circuit substrate viewed from a second face of the substrate unit;

FIG. 14A through FIG. 14D illustrate a stress of a substrate unit in accordance with a fifth embodiment;

FIG. 15 illustrates an overview of a server including a chassis where a substrate unit is mounted;

FIG. 16 illustrates an overview of a mobile phone including a chassis where a substrate unit is mounted; and

FIG. 17 illustrates an overview of a personal computer including a chassis having a substrate unit.

### DESCRIPTION OF EMBODIMENTS

A description will be given of following embodiments with reference to drawings. A size or a ratio of each portion may not correspond to those of an actual structure in the drawings. Details may be omitted in the drawings.

### First Embodiment

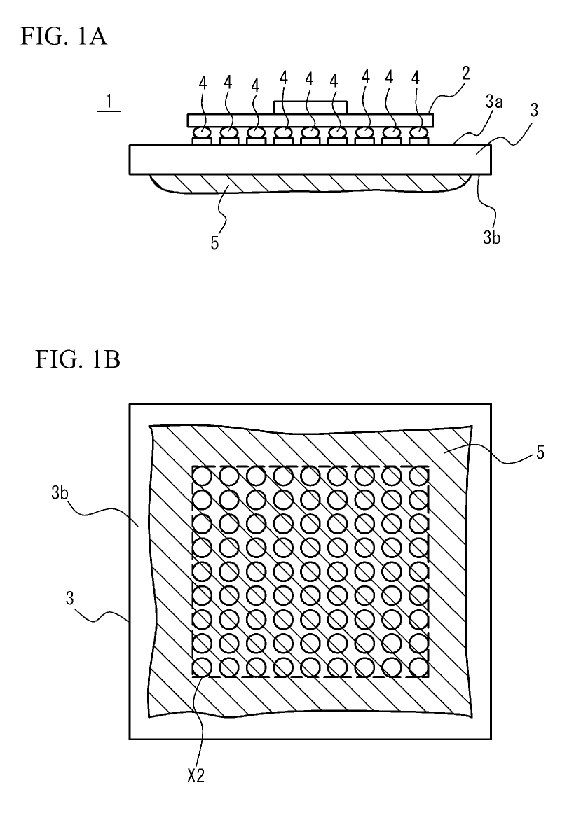

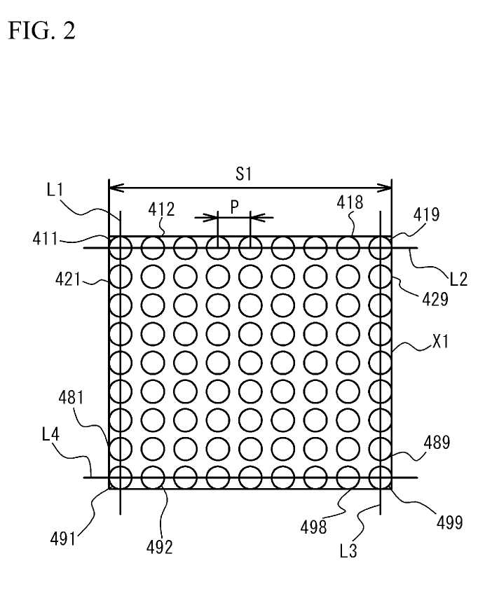

FIG. 1A and FIG. 1B illustrate a schematic view of a substrate unit 1 in accordance with a first embodiment. FIG. 1A illustrates a front view of the substrate unit 1. FIG. 1B illustrates a circuit substrate 3 viewed from a second face 3b. The substrate unit 1 includes a semiconductor device 2 as an example of an electronic component. The semiconductor device 2 has a rectangular shape. The substrate unit 1 includes the circuit substrate 3 on which the semiconductor device 2 is mounted. The circuit substrate 3 is made of resin-based substrate such as a glass fabric epoxy resin having a metal interconnection layer. The metal interconnection layer may be made of multiple layers. The semiconductor device 2 has a plurality of electrodes 4 arranged in a rectangular. The semiconductor device 2 is mounted on and jointed to a first face 3a of the circuit substrate 3 with Ball Grid Array (BGA). A description will be given of the arrangement of the electrodes 4 of the semiconductor device 2 with reference to FIG. 2. The electrodes 4 are totally arranged in a square. The semiconductor device 2 in accordance with the first embodiment has 81 of the electrodes 4 arranged in 9 columns×9 lines. Reference numerals are added to each of the electrodes 4 in order to simplify the following description. For example, a reference numeral “411” is added to the electrode 4 of a first line and a first column. A reference numeral “412” is added to another electrode 4 of the first line and a second column. A reference numeral “499” is added to another electrode 4 of a ninth line and a ninth column. These electrodes 4 are jointed to the first face 3a of the circuit substrate 3 with a solder, and form a solder-jointing portion.

The circuit substrate 3 has a resin-coated portion 5 corresponding to the rectangular arrangement of the electrodes 4 on the second face 3b on an opposite side of the first face 3a. The resin-coated portion 5 is formed by coating thermosetting resin on the second face 3b and hardening the thermosetting resin with heating.

The resin-coated portion 5 covers a projected area X2 and an external area of the projected area X2 as illustrated in FIG. 1B. The projected area X2 is an area of the second face 3b to which the rectangular formed with the electrodes 4 is projected. The electrodes 4 are arranged in the above-mentioned matrix of 9 lines×9 columns. A distance between each of the electrodes 4 is set to be “P”. Tangent lines of outermost electrodes 4 (the electrodes 411 through 491, the electrode 411 through 419, the electrode 419 through the electrode 499 and the electrodes 491 through 499) form an area X1. The projected area X2 is an area of the second face 3b to which the area X1 is projected. The substrate unit 1 having the resin-coated portion 5 covering the projected area X2 and the external area of the projected area X2 may release a stress generated at the solder-jointing portion.

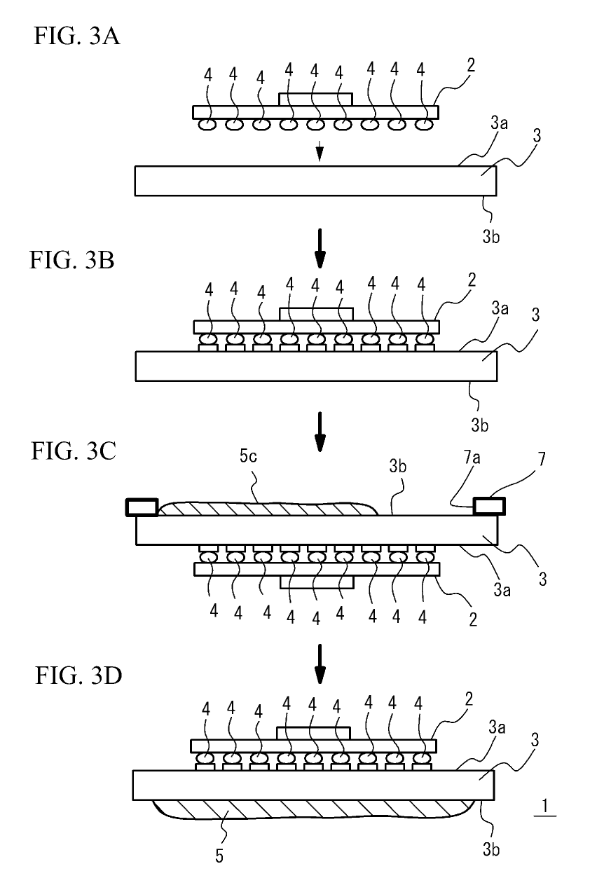

Next, a description will be given of a method of manufacturing the substrate unit 1 having the resin-coated portion 5 with reference to FIG. 3A through FIG. 3D. A plurality of the electrodes 4 arranged in a rectangular of the semiconductor device 2 acting as the electronic component are jointed to the first face 3a of the circuit substrate 3. The electrodes 4 are solder-jointed with a reflow method. Another electronic component is mounted at the stage if the electronic components are to be mounted on the second face 3b. Conductive adhesive agent may be used instead of the solder. As illustrated in FIG. 3C, a thermosetting resin 5c is coated by printing on an area of the second face 3b corresponding to the arrangement of the electrodes 4 on an opposite side of the first face 3a. A sheet member 7 having an opening 7a according to an area where the resin-coated portion 5 is to be formed is overlapped with the second face 3b. A liquid resin is provided into the opening 7a. And the resin is coated on the second face 3b. The thermosetting resin 5c may be coated with a dispenser. Then, the resin-coated portion 5 is formed by heating and hardening the thermosetting resin. It is not necessary to prepare a strengthening member by cutout or the like with respect to the substrate unit 1. In the embodiment, a resin is only coated on the second face 3b and the resin is only hardened. It is therefore possible to strengthen the substrate unit 1 easily.

The resin may be coated with variable methods such as a transcription instead of the dispense and the printing. A sheet-shaped resin may be prepared, pasted and hardened. The resin may be coated with more than one step. The shape of the resin-coated portion 5 may be another one other than rectangular such as a circle if the resin-coated portion 5 covers the projected area X2. If there is another electronic component on the coated area, the resin may be coated around or on the electronic component.

In the embodiment, the resin-coated portion 5 is made of the thermosetting resin. However, ultraviolet curable resin may be used. Another resin may be used if the resin is liquid at the coating, is hardened in processes after the coating, and has a desirable strengthening effect.

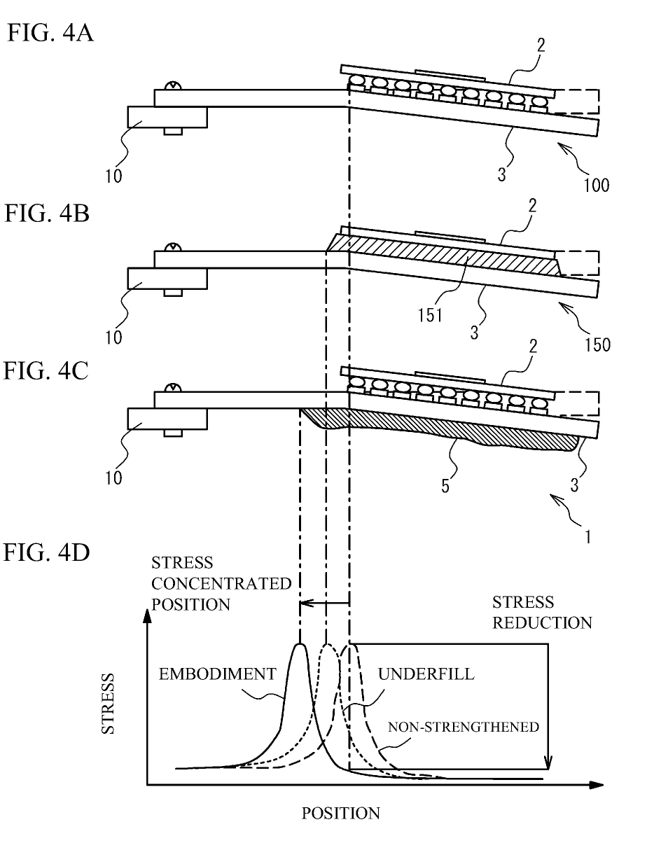

A description will be given of stress releasing in the substrate unit 1 in accordance with the embodiment with reference to FIG. 4A through FIG. 4D. FIG. 4A illustrates a case where a stay 10 supports a non-strengthened substrate unit 100 in which only the semiconductor device 2 is jointed to the circuit substrate 3 with the BGA, as a cantilever beam. FIG. 4B illustrates a case where the stay 10 supports a substrate unit 150 in which the semiconductor device 2 is jointed to the circuit substrate 3 with the BGA and an underfill 151 is formed between the circuit substrate 3 and the semiconductor device 2, as a cantilever beam. FIG. 4C illustrates a case where the stay 10 supports the substrate unit 1 in accordance with the embodiment as a cantilever beam. FIG. 4D illustrates a position where a stress is concentrated when an end part of the substrate units 1, 100 and 150 is subjected to an external force.

As illustrated in FIG. 4A, stress is concentrated along the solder-jointing portion (that is, along circumference edge of the area X1 shown in FIG. 2) in the substrate unit 100 in which the semiconductor device 2 is jointed to the circuit substrate 3 with the BGA. The solder-jointing portion may be broken or may crack if the stress is concentrated at the solder-jointing portion.

Next, as illustrated in FIG. 4B, a stress is concentrated at an end part of the underfill 151 in the substrate unit 150 in which the underfill 151 is formed between the circuit substrate 3 and the semiconductor device 2. Stress-concentrating region may shift from the solder-jointing portion if the underfill 151 is formed. However, the underfill 151 is disadvantageous when the semiconductor device 2 is detached from the circuit substrate 3. That is, it is difficult to remove the underfill 151 because the underfill 151 enters between the arrayed electrodes 4. Therefore, it may be difficult to re-use the semiconductor device 2.

In the substrate unit 1 in accordance with the embodiment, the stress-concentrating region shifts from the solder-jointing portion. And, it is easy to detach the semiconductor device 2, being different from the case where the underfill 151 is formed. That is, it is easy to detach the semiconductor device 2 from the circuit substrate 3 by melting the solder, because the semiconductor device 2 is only jointed to the circuit substrate 3 with the solder.

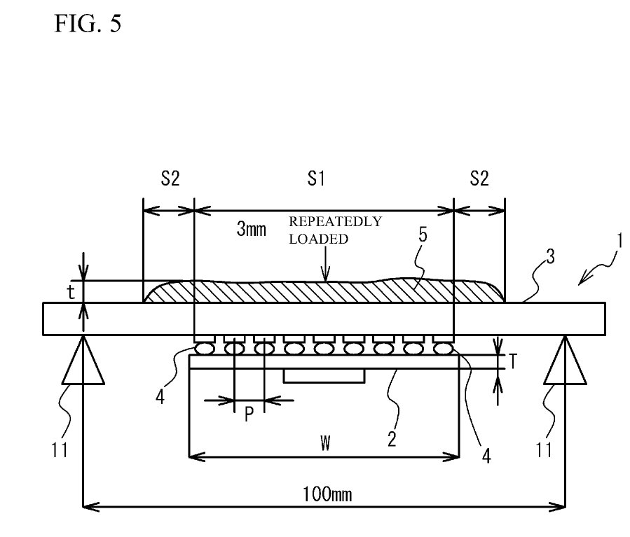

Next, a description will be given of a strength test of the substrate unit 1 in which the stress-concentrating region shifts from the solder-jointing portion. A result of a reverse bend test shown in FIG. 5 will be given, compared to the test result of the substrate unit 100 shown in FIG. 4A.

In the reverse bend test, a distance between supporting points 11 was set to be 100 mm, the substrate units 1 and 100 were on the supporting points 11. The substrate unit 1 had the same structure as the substrate unit 100 except for having the resin-coated portion 5.

In the substrate unit 1, width S1 of the solder-jointing portion (that is, width S1 of the area X1 shown in FIG. 2) was 20.47 mm, and width S2 extended from the width S1 of the area X1 is 4.0 mm. Average thickness “t” of the resin-coated portion 5 was 0.5 mm. The semiconductor device 2 was a square 22 mm on a side “w”. Thickness of the circuit substrate “T” was 1.0 mm. Interval “P” between the electrodes 4 was 0.84 mm.

A center area of the substrate units 1 and 100 was repeatedly subjected to pressing force. In this case, pressing amount was 3 mm. The test result of the substrate unit 100 will be given at first. Breaking and cracking were observed with respect to a specific substrate unit 100 when the substrate unit 100 was subjected to the pressing force twice. Breaking and cracking were observed with respect to more than 50% of the substrate units 100 when the substrate units 100 were subjected to the pressing force 100 times. Breaking and cracking were observed with respect to 100% of the substrate units 100 when the substrate units 100 were subjected to the pressing force 300 times.

On the other hand, one of the substrate units 1 that was broken and cracked firstly withstood 1363 times pressing force. Breaking and cracking were not observed with respect to 100% of the substrate units 1 until the substrate units 1 were subjected to the pressing force 5728 times.

Therefore, strength is greatly improved with respect to the substrate unit 1, compared to the substrate unit 100 not having the resin-coated portion 5.

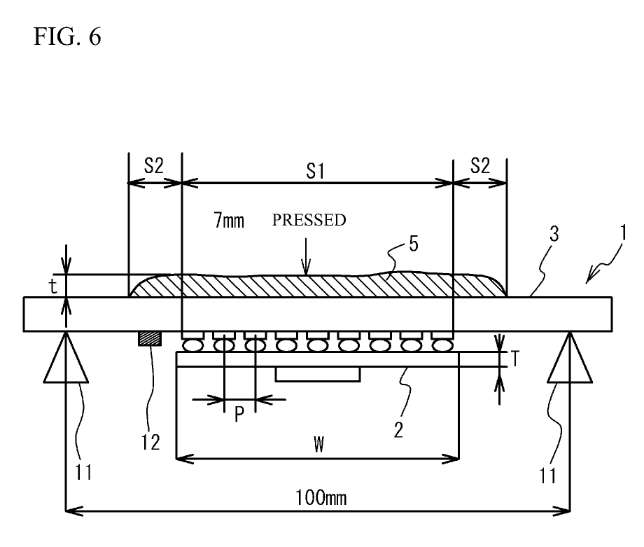

Next, a description will be given of a distortion test of the substrate unit 1 with reference to FIG. 6. A description of the test result will be given, compared to the test result of the substrate unit 100 illustrated in FIG. 4A. In the distortion test, the substrate units 1 and 100 were set as well as the reverse bend test illustrated in FIG. 5. The center area of the substrate units 1 and 100 were pressed, and distortion amount at the center area was measured. A distortion gage 12 was attached to the semiconductor device 2 at a position 5 mm inside from the end part thereof, as illustrated in FIG. 6.

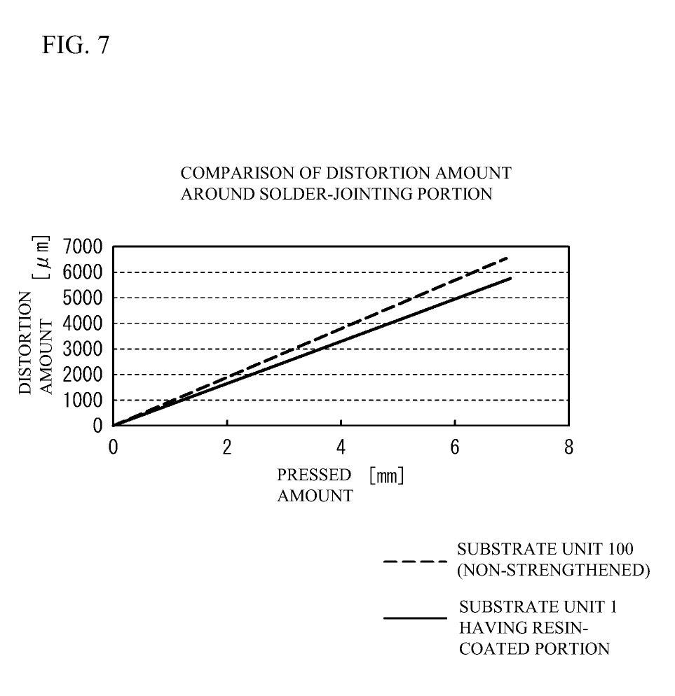

As illustrated in FIG. 7, the distortion amount of the substrate unit 1 having the resin-coated portion 5 was reduced more than that of the non-strengthened substrate unit 50. For example, the distortion amount of the substrate unit 50 was 6649 με when the pressing amount was 7 mm. In contrast, the distortion amount of the substrate unit 1 was 5739 με when the pressing amount was 7 mm. Therefore, the distortion amount of the substrate unit 1 was reduced by 13% with respect to the substrate unit 50.

The measuring result was of the position 5 mm inside from the end part of the semiconductor device 2. It is guessed that distortion amount is more reduced at the end part of the solder-jointing portion (that is, the outer circumference edge of the area X1 illustrated in FIG. 2.)

As mentioned above, the substrate unit 1 in accordance with the embodiment has necessary strength, because the substrate unit 1 has the resin-coated portion 5. It is possible to adjust the strength by adjusting the thickness of the resin-coated portion 5. It is possible to control the position of the stress concentrated region by adjusting the size of the resin-coated portion 5 (for example, the size S2 illustrated in FIG. 5 or FIG. 6). It is possible to design a stress of a chassis including the substrate unit 1 when a structure of an electronic component such as information processor is designed, if the stress-concentrated area is controllable. It is therefore possible to design an efficient structure.

It is possible to re-use the detached semiconductor device 2 because it is easy to detach the semiconductor device 2 from the circuit substrate 3 in the substrate unit 1. And it is possible to re-produce the circuit substrate 3 and mount another semiconductor device on the circuit substrate 3.

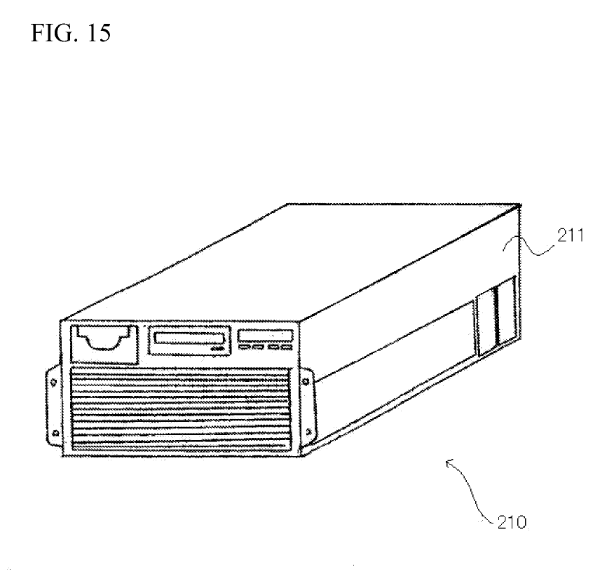

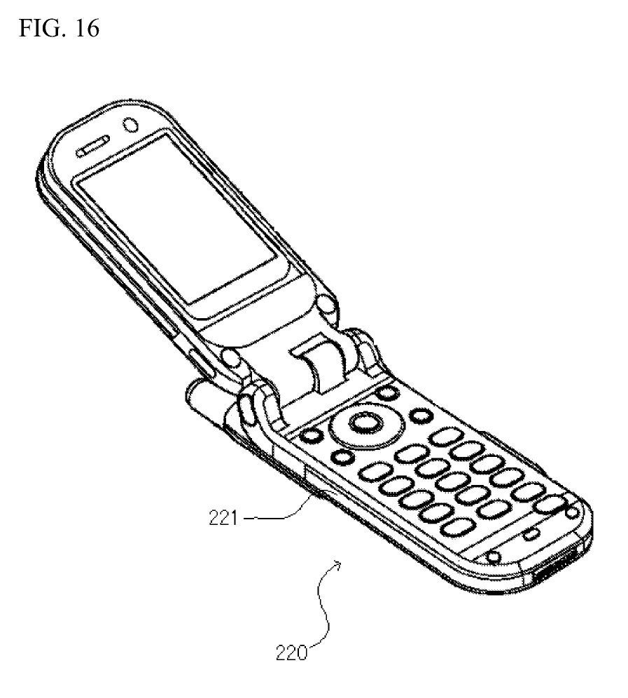

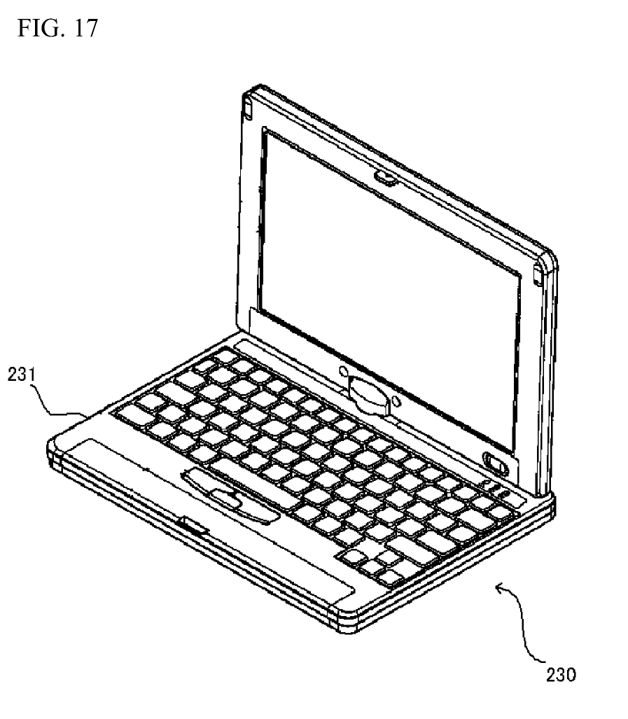

The substrate unit 1 is mounted on a chassis of variable electronic components or variable information processors. The substrate unit 1 may be mounted on a chassis 211 of a server 210 illustrated in FIG. 15, may be mounted on a chassis 221 of a mobile phone 220 illustrated in FIG. 16, and may be mounted on a chassis 231 of a personal computer 230 illustrated in FIG. 17. These electronic components and information processors are only an example. The substrate unit 1 may be mounted on a chassis of another electronic component or another information processor.

### Second Embodiment

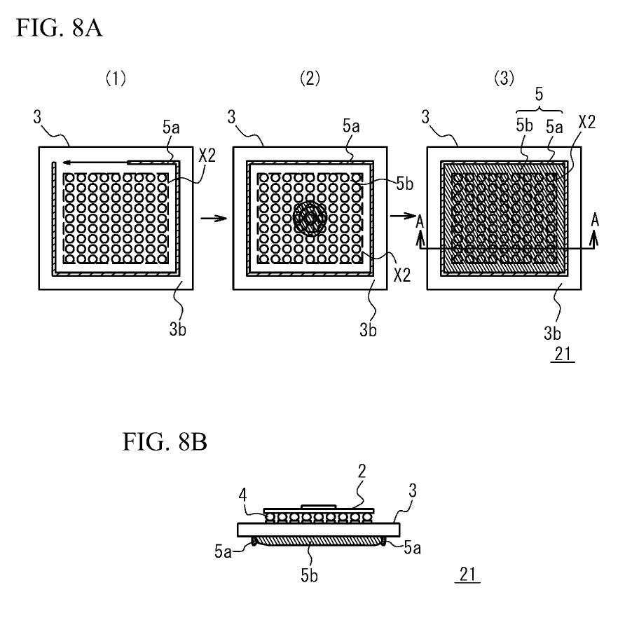

Next, a description will be given of a second embodiment with reference to FIG. 8A (1) through FIG. 8A (3) and FIG. 8B. FIG. 8A (1) through FIG. 8A (3) illustrate a part of a manufacturing flow of a substrate unit 21 in accordance with the second embodiment. FIG. 8B illustrates a cross sectional view taken along a line A-A of FIG. 8A (3). In the substrate unit 1 in accordance with the first embodiment, the resin-coated portion 5 is formed of a single resin. In contrast, in the substrate unit 21 in accordance with the second embodiment, the resin-coated portion 5 includes an outer circumference portion 5a and an inner circumference portion 5b formed of a resin different from that of the outer circumference portion 5a. That is, the resin-coated portion 5 of the substrate unit 21 in accordance with the second embodiment includes the outer circumference portion 5a and the inner circumference portion 5b inside of the outer circumference portion 5a. The outer circumference portion 5a is formed of a resin having high shape stability before hardening. The inner circumference portion 5b is formed of a resin having shape stability before hardening less than that of the outer circumference portion 5a. The shape stability of the resin before hardening may be estimated with viscosity of the resin. The shape stability of the resin before hardening has an effect on coating efficiency of the resin. The outer circumference portion 5a in accordance with the second embodiment is formed of a thermosetting resin having viscosity of 50 Pa·s or more before hardening. The inner circumference portion 5b is formed of a thermosetting resin having viscosity of 30 Pa·s.

Next, a description will be given of a manufacturing method of the substrate unit 21 having the resin-coated portion 5 including the outer circumference portion 5a and the inner circumference portion 5b. The manufacturing method of the substrate unit 21 includes a coating step of resin, being different from the manufacturing method of the substrate unit 1 illustrated in FIG. 3A through FIG. 3D. The substrate unit 21 has the same structure as the substrate unit 1 except for the structure of the resin-coated portion 5. The same components have the same reference numerals in order to avoid a duplicated explanation.

A plurality of the electrodes 4 arranged in a rectangular of the semiconductor device 2 acting as the electronic component are jointed to the first face 3a of the circuit substrate 3, as well as the processes illustrated in FIG. 3A and FIG. 3B. The electrodes 4 are solder-jointed with a reflow method. Another electronic component is mounted at the stage if the electronic components are to be mounted on the second face 3b. Conductive adhesive agent may be used instead of the solder. As illustrated in FIG. 8A (1), a thermosetting resin is coated with a dispenser on an area of the second face 3b corresponding to the arrangement of the electrodes 4 on an opposite side of the first face 3a. In concrete, high viscosity thermosetting resin is coated in a frame shape outside of the projected area X2. The coated resin will be the outer circumference portion 5a of the resin-coated portion 5 after hardening. The coated resin may have viscosity of 50 Pa·s or more before hardening. After coating the resin in the frame shape, another thermosetting resin having viscosity lower than that of the coated resin illustrated in FIG. 8A (2) is coated inside of the coated resin. The resin will be the inner circumference portion 5b of the resin-coated portion 5 after hardening. The resin may have viscosity of 30 Pa·s before hardening. Then, the thermosetting resin is heated and hardened. And the resin-coated portion 5 including the outer circumference portion 5a and the inner circumference portion 5b is formed, as illustrated in FIG. 8A (3). It is not necessary to prepare a strengthening member by cutout or the like with respect to the substrate unit 21. In the embodiment, a resin is only coated on the second face 3b and the resin is only hardened. It is therefore possible to strengthen the substrate unit 21 easily. It is possible to form the resin-coated portion 5 efficiently when the high viscosity thermosetting resin is formed in the frame shape before hardening. That is, the high viscosity thermosetting resin has high shape retaining and unflowable. The resin may be coated efficiently over an extending area if the high shape retaining resin is formed in the frame shape in advance and low viscosity thermosetting resin is flown inside of the frame shaped resin.

The resin may be coated with variable methods such as a transcription instead of the dispense and the printing. A sheet-shaped resin may be prepared, pasted and hardened. The resin may be coated with more than one step. The shape of the resin-coated portion 5 may be another one other than rectangular such as a circle if the resin-coated portion 5 covers the projected area X2. If there is another electronic component in the coated area, the resin may be coated around or on the electronic component. These points are the same as the first embodiment. Only the resin of the outer circumference portion 5a may be coated and hardened, and after that, the resin of the inner circumference portion 5b may be coated and hardened.

Two types resins are used for the outer circumference portion 5a and the inner circumference portion 5b included in the resin-coated portion 5 in accordance with the second embodiment in order to emphasize easy coating of resin. Resin may be selected in view of resin property after hardening.

That is, it is preferable that the resin forming the outer circumference portion 5a is selected based on high strength after hardening. That is, it is preferable that the outer circumference portion 5a has as high strength as possible, because the stress is concentrated around the outer circumference portion 5a when the substrate unit 21 is subjected to an external force. On the other hand, it is preferable that the resin forming the inner circumference portion 5b is selected based on flexibility after hardening. That is, it is preferable that the inner circumference portion 5b has flexibility and follow the expansion of the substrate unit 21 when the substrate unit 21 is heated and expands a little.

The resin forming the outer circumference portion 5a and the inner circumference portion 5b may be selected in view of above-mentioned points. It is preferable that the resin is selected based on the property after hardening with the high coating efficiency of the second embodiment being kept. However, the resin may be selected only based on the property after hardening.

The substrate unit 21 has the same effect as the substrate unit 1 in accordance with the first embodiment. That is, the substrate unit 21 has necessary strength because the substrate unit 21 has the resin-coated portion 5. The strength may be adjusted by adjusting the thickness of the resin-coated portion 5. And, the position of the stress concentrated region may be controlled.

It is possible to re-use the detached semiconductor device 2 because it is easy to detach the semiconductor device 2 from the circuit substrate 3 in the substrate unit 21. And it is possible to re-produce the circuit substrate 3 and mount another semiconductor device on the circuit substrate 3.

The substrate unit 21 may be mounted on a chassis of variable electronic components or variable information processors, as well as the substrate unit 1 in accordance with the first embodiment. The substrate unit 21 may be mounted on the chassis 211 of the server 210 illustrated in FIG. 15, may be mounted on the chassis 221 of the mobile phone 220 illustrated in FIG. 16, and may be mounted on the chassis 231 of the personal computer 230 illustrated in FIG. 17. The substrate unit 21 may be mounted on a chassis of another electronic component or another information processor.

The resin forming the resin-coated portion 5 may be ultraviolet curable resin, as well as the first embodiment.

### Third Embodiment

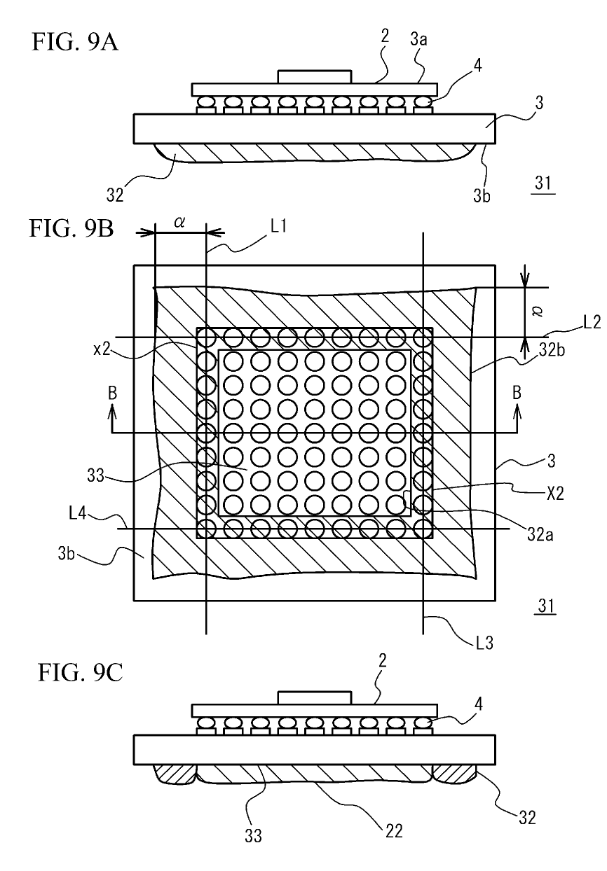

Next, a description will be given of a third embodiment. FIG. 9A through FIG. 9C illustrate an overview of a substrate unit 31 in accordance with the third embodiment. FIG. 9A illustrates a front view of the substrate unit 31. FIG. 9B illustrates the circuit substrate 3 viewed from the second face 3b. FIG. 9C illustrates a cross sectional view taken along a line B-B of FIG. 9B. The substrate unit 31 has a resin-coated portion 32 having a frame shape illustrated in FIG. 9B, being different from the substrate unit 1 in accordance with the first embodiment. Resin is not coated on an inner area 33 inside of the resin-coated portion 32. The resin-coated portion 32 is formed in a frame shape along an outer circumference edge of the projected area X2 that is an area of the second face 3b to which the rectangular formed with the electrodes 4 is projected. The resin-coated portion 32 covers up to outside of the outer circumference edge of the projected area X.

A description will be given of a size and an arrangement of the frame-shaped resin-coated portion 32 with reference to FIG. 2. A centerline of the electrodes 411 through 491 positioned at an outer circumference of the area X1 is defined as a centerline L1. Similarly, a centerline of the electrodes 411 through 419 is defined as a centerline L2. A centerline of the electrodes 419 through 499 is defined as a centerline L3. A centerline of the electrodes 491 through 499 is defined as a centerline L4.

An inner circumference edge 32a of the frame-shaped resin-coated portion 32 in positioned on the centerlines L1 through L4, or is positioned inside of the centerlines L1 through L4. On the other hand, an outer circumference region 32b of the frame-shaped resin-coated portion 32 is positioned outside of the centerlines L1 through L4 by a distance “α”. Here, the distance “α” may be optionally set according to a design condition if the distance “α” is larger than a half of the distance “P” between the electrodes 4 (hereinafter referred to as P/2). This is because the resin-coated portions covers up to the edge of the outer circumference electrodes 4 if the circumference sides are positioned outside of the centerlines L1 through L4 by at least P/2. In this case, the resin-coated portion 32 covers up to the outer circumference edge of the projected area X2 and the stress-concentrated area may shift outside of the solder-jointing portion.

The substrate unit 31 has the same effect as the substrate unit 1 in accordance with the first embodiment. That is, the substrate unit 31 has necessary strength because the substrate unit 31 has the resin-coated portion 32. It is possible to adjust the strength by adjusting the thickness of the resin-coated portion 32. And it is possible to control the position of the stress-concentrated region.

It is possible to re-use the detached semiconductor device 2 because it is easy to detach the semiconductor device 2 from the circuit substrate 3 in the substrate unit 31. And it is possible to re-produce the circuit substrate 3 and mount another semiconductor device on the circuit substrate 3.

The substrate unit 31 may be mounted on a chassis of variable electronic components or variable information processors, as well as the substrate unit 1 in accordance with the first embodiment.

The resin forming the resin-coated portion 5 may be ultraviolet curable resin, as well as the first embodiment.

Expansion of the circuit substrate 3 is not restrained when the circuit substrate 3 is heated, because resin is not coated on the inner area 33. Therefore, the substrate unit 31 restrains thermal stress.

Further, resin amount of the substrate unit 31 may be reduced, compared to the substrate unit 1 in accordance with the first embodiment.

### Fourth Embodiment

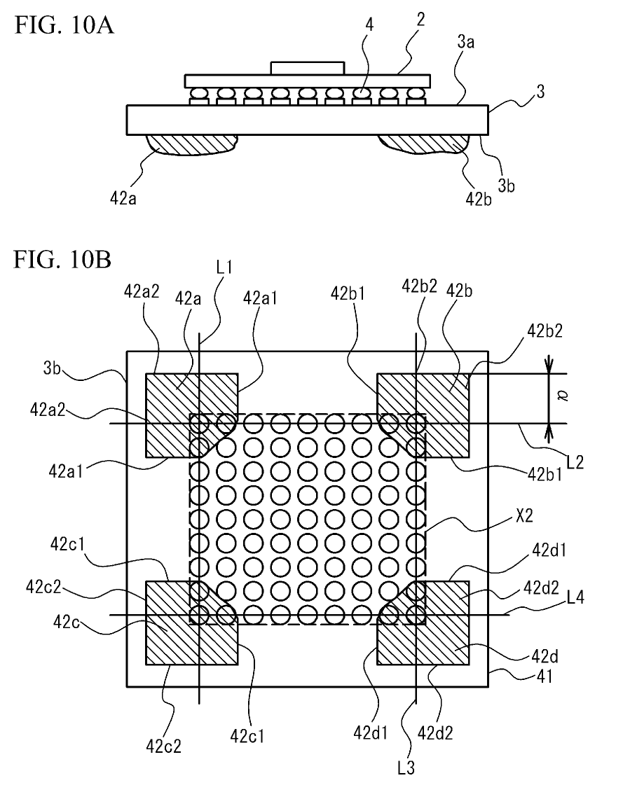

A description will be given of a fourth embodiment with reference to FIG. 10A and FIG. 10B. FIG. 10A and FIG. 10B illustrate an overview of a substrate unit 41 in accordance with the fourth embodiment. FIG. 10A illustrates a front view of the substrate unit 41. FIG. 10B illustrates the circuit substrate 3 viewed from the second face 3b.

The substrate unit 41 has four resin-coated portions 42a, 42b, 42c and 42d. The resin-coated portions 42a through 42d are provided so as to cover areas of the second face 3b to which the electrodes 411, 419, 491 and 499 are projected. The electrodes 411, 419, 491 and 499 are corner electrodes of the electrodes 4 arranged in the rectangular.

In FIG. 10B, each of the resin-coated portions 42a through 42d covers three of the electrodes 4. That is, the resin-coated portion 42a covers a projected area of the electrodes 411, 412 and 421. The resin-coated portion 42b covers a projected area of the electrodes 419, 418 and 429. The resin-coated portion 42c covers a projected area of the electrodes 491, 481 and 492. The resin-coated portion 42d covers a projected area of the electrodes 499, 489 and 498.

It is preferable that the resin-coated portions 42a through 42d satisfy the following conditions. An inner circumference side 42a1 of the resin-coated portion 42a is preferably positioned on the centerline L1 or L2 illustrated in FIG. 2, or is inside of the centerlines L1 and L2. An outer circumference side 42a2 of the resin-coated portion 42a is preferably positioned outside of the centerlines L1 and L2 by a distance “α”.

An inner circumference side 42b1 of the resin-coated portion 42b is preferably positioned on the centerline L2 or L3 illustrated in FIG. 2, or is inside of the centerlines L2 and L3. An outer circumference side 42b2 of the resin-coated portion 42b is preferably positioned outside of the centerlines L2 and L3 by the distance “α”.

An inner circumference side 42c1 of the resin-coated portion 42c is preferably positioned on the centerline L1 or L3 illustrated in FIG. 2, or is positioned inside of the centerlines L1 and L3. An outer circumference side 42c2 of the resin-coated portion 42c is preferably positioned outside of the centerlines L1 and L4 by the distance “α”.

An inner circumference side 42d1 of the resin-coated portion 42d is preferably positioned on the centerline L3 or L4 illustrated in FIG. 2, or is positioned inside of the centerlines L3 and L4. An outer circumference side 42d2 of the resin-coated portion 42d is preferably positioned outside of the centerlines L3 and L4 by the distance “α”.

The distance “α” may be optionally set according to a design condition if the distance “α” is larger than a half of the distance “P” between the electrodes 4 (hereinafter referred to as P/2). This is because the resin-coated portions covers up to the edge of the outer circumference electrodes 4 if the circumference sides are positioned outside of the centerlines L1 through L4 by at least P/2. In this case, the stress-concentrated area may shift outside of the solder-jointing portion.

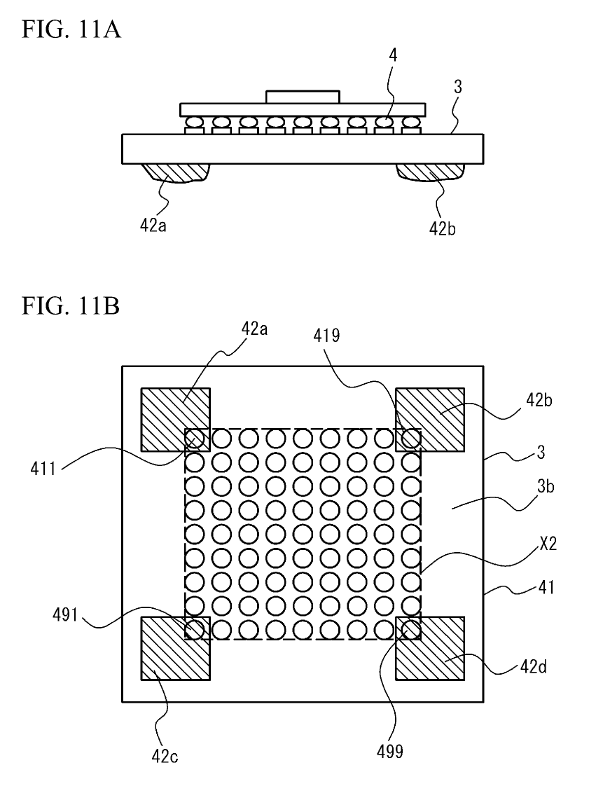

If the above-mentioned conditions are satisfied, the size and the arrangement of the resin-coated portions 42a through 42d may be changed optionally. FIG. 11A and FIG. 11B illustrate another example of the resin-coated portions 42a through 42d. As illustrated in FIG. 11A and FIG. 11B, the resin-coated portions 42a through 42d may be respectively formed so as to cover a single area to which a single electrode 4 is projected. In FIG. 11A and FIG. 11B, the resin-coated portion 42a covers an area to which the electrode 411 is projected. The resin-coated portion 42b covers an area to which the electrode 419 is projected. The resin-coated portion 42c covers an area to which the electrode 491 is projected. The resin-coated portion 42d covers an area to which the electrode 499 is projected. The size, the shape and the arrangement of the resin-coated portions 42a through 42d may be changed if required.

The substrate unit 41 has the same effect as the substrate unit 1. However, the strength of the substrate (for example, maximum strength or stress concentrated region) may be changed according to the size and the arrangement of the resin-coated portion. Therefore, the resin-coated portions in accordance with above-mentioned embodiments may be used in a substrate unit according to required strength or design condition. The size, the shape and the arrangement may be selected if necessary.

In the fourth embodiment, it is possible to re-use the detached semiconductor device 2 because it is easy to detach the semiconductor device 2 from the circuit substrate 3, as well as the first embodiment.

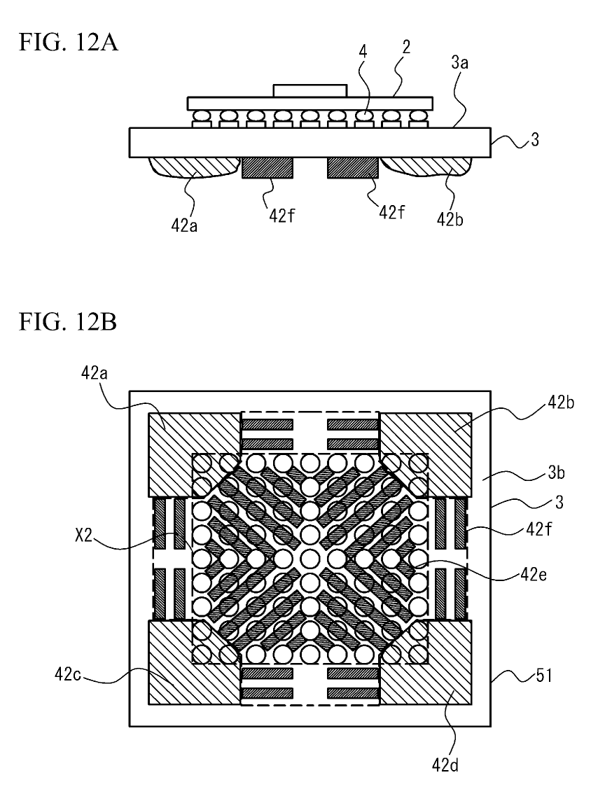

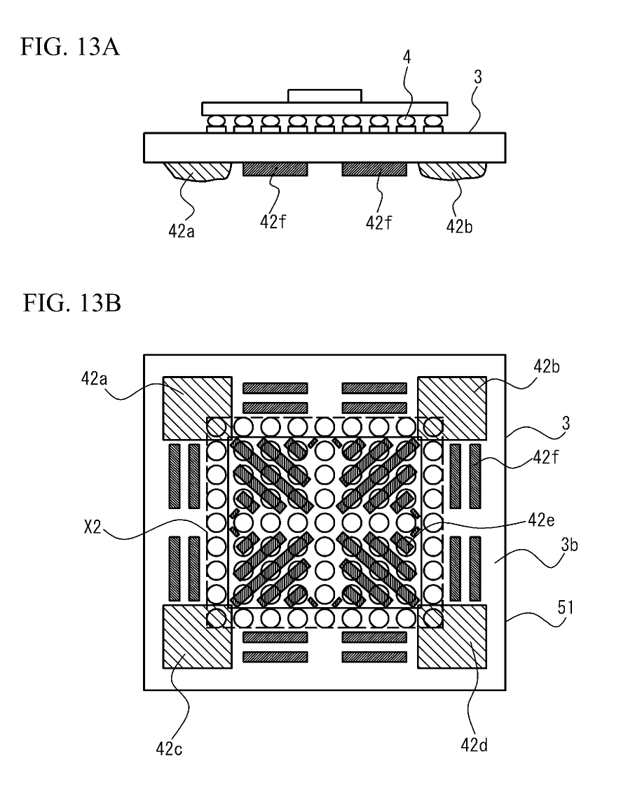

A substrate unit may have variable resin-coated portions according to a required property. A resin-coated portions 42e and 42f may be provided on an area surrounded by the resin-coated portions 42a through 42d, as in the case of a substrate unit 51 illustrated in FIG. 12A through FIG. 13B. The resin-coated portions 42e and 42f are an example, and a resin-coated portion group in which the resin-coated portions 42e and 42f are axisymmetrically arranged with respect to a longitudinal centerline and a lateral centerline of the semiconductor device 2. The size, the shape and the arrangement of the resin-coated portions 42e and 42f may be changed optionally. And resin property of the resin-coated portions 42e and 42f may be changed if necessary. For example, the resin may be selected in view of strength against an external force. And, for example, a resin restraining thermal degradation may be selected and coated in view of thermal degradation of the substrate unit 51. The resin of the resin-coated portions 42e and 42f may be different from that of the resin-coated portions 42a through 42d.

### Fifth Embodiment

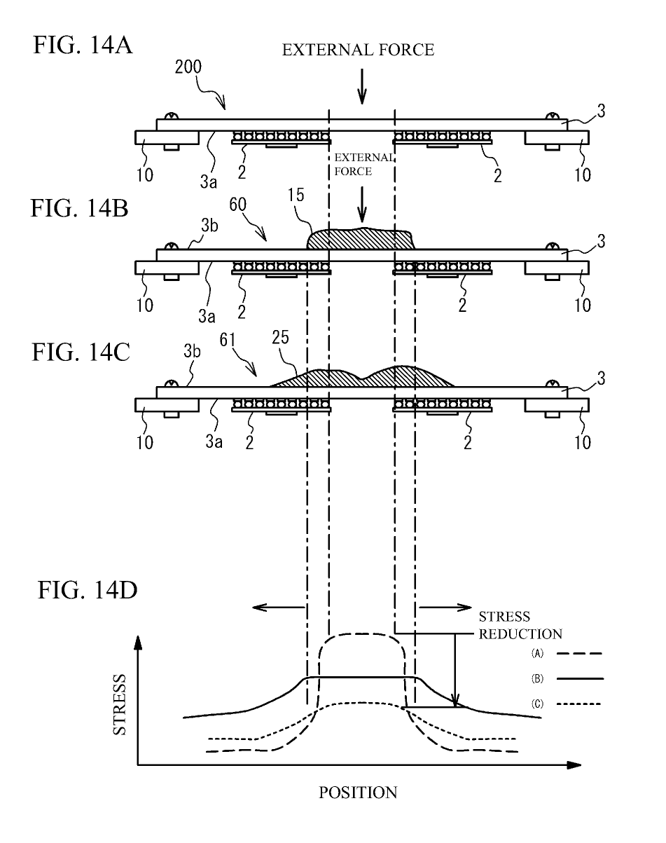

A description will be given of a fifth embodiment with reference to FIG. 14A through FIG. 14D. FIG. 14A through FIG. 14D illustrate stress releasing of substrate units 60 and 61 in accordance with the fifth embodiment. FIG. 14A illustrates a case where two stays 10 supports both end parts of a non-strengthened substrate unit 200 in which two of the semiconductor devices 2 are only jointed to the circuit substrate 3 with the BGA. FIG. 14B illustrates a case where two stays 10 support both end parts of the substrate unit 60 in which two of the semiconductor devices 2 are jointed to the circuit substrate 3 with the BGA, and a resin-coated portion 15 is formed so as to cover the edge of the two semiconductor devices 2. FIG. 14C illustrates a case where two stays 10 supports both end parts of the substrate unit 61 in which two of the semiconductor devices 2 are jointed to the circuit substrate 3 with the BGA, a resin-coated portion 25 is formed so as to cover the edge of the two semiconductor devices 2, and thickness is different according to the position thereof. FIG. 14D illustrates a stress concentrated region when the substrate units 200, 60 and 61 are subjected to an external force.

In the substrate unit 200 illustrated in FIG. 14A, a stress is concentrated along an edge of the solder-jointing portion (along outer circumference edge of the area X1 illustrated in FIG. 2). And the stress is enlarged in the substrate unit 200.

In contrast, in the substrate unit 60 illustrated in FIG. 14B, the stress concentrated region shifts inside of the edge of the solder-jointing portion, and the stress is reduced. Breaking of the substrate unit 60 may be restrained if the stress is reduced. Peeling and breaking at the edge of the solder-jointing portion may be restrained when the stress-concentrated region is shifted inside of the edge of the solder-jointing portion. The substrate unit 60 has an advantage in this point, because the electrodes 4 are in close formation in the area inside of the solder-jointing portion and the solder-jointing portion overlaps with the semiconductor device 2.

In the substrate unit 61 illustrated in FIG. 14C, the stress is reduced and the stress-concentrated region is shifted because the thickness of the resin-coated portion 25 changes. It is possible to restrain the breaking of the substrate unit 61 by reducing the stress and controlling the position of the stress-concentrated region.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A substrate unit comprising:
an electronic component having a plurality of electrodes arranged in a given shape;
a circuit substrate having a first face where the electronic component is mounted and the electrodes are jointed and a second face underside of the first face; and
a resin-coated portion formed on the second face according to a projected area of the second face to which the given shape is projected.

2. The substrate unit as claimed in claim 1, wherein
the resin-coated portion covers up to outside of the projected area of the second face to which the given shape is projected.

3. The substrate unit as claimed in claim 1, wherein:
the resin-coated portion has an outer circumference portion and an inner circumference portion inside of the outer circumference portion;
the outer circumference portion is formed of a high shape stability resin before hardening; and
the inner circumference portion is formed of a resin having shape stability before hardening lower than that of the outer circumference portion.

4. The substrate unit as claimed in claim 1, wherein:
the resin-coated portion is formed in a frame shape along an outer circumference edge of the projected area of the second face to which the given shape is projected; and
the resin-coated portion formed in the frame shape covers up to outside of the outer circumference edge of the projected area.

5. The substrate unit as claimed in claim 1, wherein the resin-coated portion is formed so as to cover areas of the second face to which corner electrodes of rectangular-arranged electrodes are projected.

6. An information processor comprising:
a substrate unit; and
a chassis on which the substrate unit is mounted,
wherein the substrate unit includes an electronic component having a plurality of electrodes arranged in a given shape, a circuit substrate having a first face where the electronic component is mounted and the electrodes are jointed and a second face underside of the first face, and a resin-coated portion formed on the second face according to a projected area of the second face to which the given shape is projected.

7. The information processor as claimed in claim 6, wherein
the resin-coated portion covers up to outside of the projected area of the second face to which the given shape is projected.

8. The information processor as claimed in claim 6, wherein:
the resin-coated portion has an outer circumference portion and an inner circumference portion inside of the outer circumference portion;
the outer circumference portion is formed of a high shape stability resin before hardening; and
the inner circumference portion is formed of a resin having shape stability before hardening lower than that of the outer circumference portion.

9. The information processor as claimed in claim 6, wherein:
the resin-coated portion is formed in a frame shape along an outer circumference edge of the projected area of the second face to which the given shape is projected; and
the resin-coated portion formed in the frame shape covers up to outside of the outer circumference edge of the projected area.

10. The information processor as claimed in claim 6, wherein the resin-coated portion is formed so as to cover areas of the second face to which corner electrodes of rectangular-arranged electrodes are projected.

11. A method of manufacturing a substrate unit comprising:
jointing a plurality of electrodes of an electronic component on a first face of a circuit substrate in a given shape with a solder or a conductive adhesive agent;
coating hardening resin on a second face underside of the first face according to the arrangement of the electrodes; and
hardening the hardening resin and forming a resin-coated portion.

12. The method as claimed in claim 11, wherein
a first resin having high viscosity is coated in a frame shape outside of a projected area of the second face to which the given shape is projected, and a second resin having viscosity lower than that of the first resin is coated inside of the frame-shaped first resin, in the coating of the hardening resin.

13. The method as claimed in claim 11 wherein the hardening resin is one of thermosetting resin and ultraviolet curable resin.
